(19) United States
(12) Patent Application Publication
(10) Pub. No.: US 2025/0203947 A1
(43) Pub. Date: Jun. 19, 2025

(54) SEMICONDUCTOR STRUCTURES AND MANUFACTURING METHODS THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/735,551

(22) Filed: Jun. 6, 2024

(30) Foreign Application Priority Data
Dec. 19, 2023 (CN) 202311754469.X

(51) Int. Cl. H01L 29/786; H01L 29/06; H01L 29/417; H01L 29/423; H01L 29/45; H01L 29/66; H01L 29/775

(52) U.S. Cl. CPC H10D 30/6757; H10D 30/014; H10D 30/43; H10D 30/6735; H10D 30/6737; H10D 30/675; H10D 62/121; H10D 30/6729

(57) ABSTRACT

The present disclosure provides a semiconductor structure. The semiconductor structure includes: a substrate; a channel structure on the substrate. The channel structure includes a first intermediate layer, a channel layer, and a second intermediate layer that are stacked. The channel structure includes a gate region and source and drain regions located at both ends of the gate region. A first N-type heavily doped layer is located between the substrate and the channel structure, and the second N-type heavily doped layer is located on the side of the channel structure far from the substrate. The projections of the first N-type heavily doped layer and the second N-type heavily doped layer on the channel structure are located within the gate region. A gate is located on the gate region. The gate covers the sidewalls of the first N-type heavily doped layer, the channel layer, and the second N-type heavily doped layer.

### CROSS REFERENCE TO RELATED APPLICATIONS

This application claims priority to Chinese Patent Application No. 202311754469X, the entire content of which is incorporated herein by reference.

### TECHNICAL FIELD

The present disclosure relates to the technical field of semiconductor, in particular to semiconductor structures and manufacturing methods therefor.

### BACKGROUND

Gallium nitride (GaN), as a representative of the third generation of wide band gap semiconductor, is attracting widespread attention. Properties of GaN mainly include high electron mobility and high two-dimensional electron gas (2DEG) concentration. In addition, GaN material has stable chemical properties, high temperature resistance and corrosion resistance, and has inherent advantages in high-frequency, high-power, and radiation-resistant applications.

In a planar device, current laterally flows in a quantum well formed by a heterojunction structure. Under a reversebias, a distribution of electric field in a device is usually uneven. Generally, severe electric field concentration occurs at an edge of the gate electrode or the drain electrode, and the electric field there increases rapidly with an increase of reverse voltage. When a critical breakdown field strength is reached, the device is broken down.

A high breakdown voltage means that the device operates in a larger voltage range, can achieve higher power density, and has higher reliability. Therefore, how to improve the gate control capability and breakdown voltage of devices is a key concern for electronic device researchers.

### SUMMARY

In view of this, the present disclosure provides a semiconductor structure and a manufacturing method therefor. The semiconductor structure is simpler compared to a typical full-surround-gate field-effect transistor structure, and the corresponding manufacturing method is also simpler.

For the first aspect, the present disclosure provides a semiconductor structure, including:
a substrate;
a channel structure on the substrate, where the channel structure includes a first intermediate layer, a channel layer, and a second intermediate layer that are stacked on the substrate, and the channel structure includes a gate region, and a source region and a drain region at both sides of the gate region;
a first N-type heavily doped layer and a second N-type heavily doped layer, where the first N-type heavily doped layer is between the substrate and the channel structure, and the second N-type heavily doped layer is on a side of the channel structure far from the substrate, and projection of the first N-type heavily doped layer on the channel structure and projection of the second N-type heavily doped layer on the channel structure are located within the gate region; and
a gate electrode within the gate region, where the gate electrode covers sidewalls of the first N-type heavily doped layer, the channel structure, and the second N-type heavily doped layer.

In some embodiments, the gate electrode is in ohmic contact with the first N-type heavily doped layer and the second N-type heavily doped layer.

In some embodiments, the semiconductor structure includes: a plurality of the channel structures that are stacked on the substrate; and
In some embodiments, a third N-type heavily doped layer between adjacent channel structures of the plurality of channel structures, and projection of the third N-type heavily doped layer on the channel structure is located within the gate region.

In some embodiments, the plurality of channel structures share the gate electrode, the gate electrode covers sidewalls of the third N-type heavily doped layer, and the gate electrode is in ohmic contact with the third N-type heavily doped layer.

In some embodiments, the semiconductor structure further includes:
a dielectric layer on the gate region, where the dielectric layer covers the sidewalls of the channel layer, and the dielectric layer is between the gate electrode and the channel layer.

In some embodiments, the channel layer is a nanowire structure or a nanosheet structure.

In some embodiments, a material of the channel structure includes a group-III nitride material.

In some embodiments, materials of the first intermediate layer and the second intermediate layer includes AlN; and
a material of the channel layer includes GaN, AlGaN, InGaN, or AlInGaN.

In some embodiments, a source electrode and a drain electrode respectively at the source region and the drain region, where the source electrode and the drain electrode wrap around the channel layer.

In some embodiments, the channel layer is an N-type lightly doped layer, and doping concentration of N-type ions for the channel layer is less than 1E18.

For the second aspect, the present disclosure further provides a manufacturing method for a semiconductor structure, including:
providing a substrate;
sequentially manufacturing a first N-type heavily doped layer, a channel structure, and a second N-type heavily doped layer on the substrate, where manufacturing the channel structure includes: manufacturing, on the first N-type heavily doped layer, a first intermediate layer, a channel layer, and a second intermediate layer that are stacked on the first N-type heavily doped layer, where the channel structure includes a gate region, and a source region and a drain region at both sides of the gate region; and
removing parts of the first N-type heavily doped layer whose projection on the channel structure is within the source region and the drain region, and parts of the second N-type heavily doped layer whose projection on the channel structure is within the source region and the drain region;
manufacturing a gate electrode within the gate region, where the gate electrode covers sidewalls of the first N-type heavily doped layer, the channel structure, and the second N-type heavily doped layer.

In some embodiments, before manufacturing the gate electrode within the gate region, the manufacturing method further includes: manufacturing a dielectric layer on the sidewalls of the first N-type heavily doped layer, the channel structure, and the second N-type heavily doped layer, and on a top of the second N-type heavily doped layer; and patterning the dielectric layer to expose a part of the first N-type heavily doped layer in the gate region and a part of the second N-type heavily doped layer in the gate region, where the gate electrode is connected to the first N-type heavily doped layer and the second N-type heavily doped layer, and the gate electrode is connected to the channel structure through the dielectric layer.

In some embodiments, after manufacturing the dielectric layer on the sidewalls of the first N-type heavily doped layer, the channel structure, and the second N-type heavily doped layer, and on the top of the second N-type heavily doped layer, the manufacturing method includes:
patterning the dielectric layer to expose parts of the first N-type heavily doped layer within the source region and the drain region, and parts of the second N-type heavily doped layer within the source region and the drain region; and removing the parts of the first N-type heavily doped layer whose projection on the channel structure is within the source region and the drain region, and the parts of the second N-type heavily doped layer whose projection on the channel structure is within the source region and the drain region.

In some embodiments, patterning the dielectric layer to expose the parts of the first N-type heavily doped layer within the source region and the drain region, and the parts of the second N-type heavily doped layer within the source region and the drain region includes: patterning the dielectric layer to expose the parts of the first N-type heavily doped layer within the source region and the drain region, the parts of the second N-type heavily doped layer within the source region and the drain region, parts of the first intermediate layer within the source region and the drain region, and parts of the second intermediate layer within the source region and the drain region; and
the method further includes: removing parts of the first intermediate layer within the source region and the drain region, and parts of the second intermediate layer within the source region and the drain region.

In some embodiments, the method further includes: respectively manufacturing a source electrode and a drain electrode at the source region and the drain region, where the source electrode and the drain electrode wrap around the channel layer.

In some embodiments, the gate electrode is in ohmic contact with the first N-type heavily doped layer and the second N-type heavily doped layer.

In some embodiments, before manufacturing the dielectric layer on the sidewalls of the first N-type heavily doped layer, the channel structure, and the second N-type heavily doped layer, and on the top of the second N-type heavily doped layer, the manufacturing method includes:
patterning the first N-type heavily doped layer, the channel structure, and the second N-type heavily doped layer, to enable the channel layer to form a nanowire structure or a nanosheet structure.

In some embodiments, manufacturing the channel structure includes: manufacturing a plurality of the channel structures that are stacked on the substrate; and
the method further includes: manufacturing a third N-type heavily doped layer, where the third N-type heavily doped layer is between adjacent channel structures in the plurality of channel structures, and the gate electrode is connected to the third N-type heavily doped layer, and the gate electrode is in ohmic contact with the third N-type heavily doped layer.

In some embodiments, removing the parts of the first N-type heavily doped layer whose projection on the channel structure is within the source region and the drain region, and the parts of the second N-type heavily doped layer whose projection on the channel structure is within the source region and the drain region includes:
removing the parts of the first N-type heavily doped layer whose projection on the channel structure is within the source region and the drain region, the parts of the second N-type heavily doped layer whose projection on the channel structure is within the source region and the drain region, and parts of the third N-type heavily doped layer whose projection on the channel structure is within the source region and the drain region.

In some embodiments, after manufacturing the channel layer, the manufacturing method further includes:
performing N-type doping on the channel layer, where doping concentration of N-type ions is less than 1E18.

### BRIEF DESCRIPTION OF DRAWINGS

FIG. 1 is a schematic diagram of a semiconductor structure provided in an embodiment 1 of the present disclosure.

FIG. 2 is a schematic cross-sectional diagram of a gate region of a semiconductor structure provided in the embodiment 1 of the present disclosure.

FIG. 3 is a schematic diagram of a semiconductor structure provided in an embodiment 2 of the present disclosure.

FIG. 4 is a schematic cross-sectional diagram of a gate region of a semiconductor structure provided in the embodiment 2 of the present disclosure.

FIGS. 5 to 11 are schematic diagrams of a manufacturing process for a semiconductor structure provided in an embodiment 3 of the present disclosure.

FIG. 12 is an intermediate schematic diagram of a manufacturing process for a semiconductor structure provided in an embodiment 4 of the present disclosure.

FIG. 13 is another intermediate schematic diagram of a manufacturing process for a semiconductor structure provided in an embodiment 4 of the present disclosure.

### DETAILED DESCRIPTION

Embodiments will be described in detail herein, examples of which are illustrated in the accompanying drawings. Where the following description refers to the drawings, elements with the same numerals in different drawings refer to the same or similar elements unless otherwise indicated. Implementations described in the following embodiments do not represent all implementations consistent with the present disclosure. On the contrary, they are examples of an apparatus and a method consistent with some aspects of the present disclosure described in detail in the appended claims.

The terms used in this specification are only for the purpose of describing particular embodiments and are not intended to limit the specification. As used in the present disclosure and the appended claims, the singular forms “a”, “an” and “the” are intended to include the plural forms as well, unless the context clearly indicates otherwise. It should further be understood that the term “and/or” as used herein refers to and includes any and all possible combinations of one or more of the associated listed items.

It should be understood that although the terms first, second, third, etc. may be used in this specification to describe various objects, such objection should not be limited to these terms. These terms are only used to distinguish one category of objects from another. For example, without departing from the scope of the present disclosure, a first intermediate layer can also be referred to as a second intermediate layer, and similarly, a second intermediate layer can also be referred to as a first intermediate layer.

Embodiments of the present disclosure are described herein with reference to cross-section diagrams of the schematic illustrations of preferred embodiments of the present disclosure. As such, variations from the shapes as shown due to, for example, manufacturing techniques and/or tolerances can be anticipated. Therefore, embodiments of the present disclosure should not be limited to specific shapes of the regions as shown, but rather include shape deviations caused by, for example, manufacturing. For example, an implantation region illustrated as rectangles typically have circular or curved features at its edges and/or an implantation concentration gradient, while it is not a binary change from an implantation region to a non-implantation region. Similarly, a buried region formed by implantation can lead to some implantation in regions between the buried region and a surface through which the injectant passes during implantation. Therefore, the regions shown in the drawings are essentially schematic, and their shapes are not intended to illustrate an actual shape of a region of a device and is not intended to limit the scope of the present disclosure.

### Embodiment 1

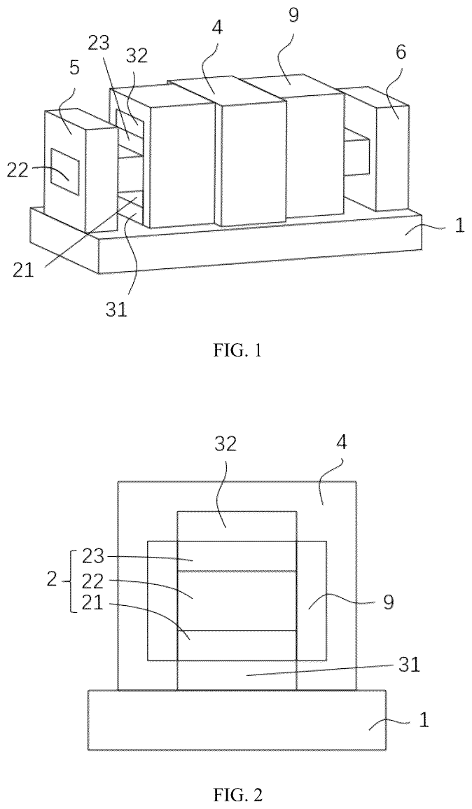

Embodiment 1 of the present disclosure provides a semiconductor structure. FIG. 1 is a schematic diagram of a semiconductor structure provided in the embodiment 1 of the present disclosure. As shown in FIG. 1, the semiconductor structure includes: a substrate 1; a channel structure 2 on the substrate 1, and a gate electrode 4. The channel structure 2 includes a first intermediate layer 21, a channel layer 22, and a second intermediate layer 23 that are stacked on substrate 1. The channel structure 2 includes a gate region, and a source region and a drain region located at both sides of the gate region. The first N-type heavily doped layer 31 is located between the substrate 1 and the channel structure 2. The second N-type heavily doped layer 32 is located on the side of channel structure 2 far from the substrate 1. The projections of the first N-type heavily doped layer 31 and the second N-type heavily doped layer 32 on channel structure 2 are located in the gate region. The gate electrode 4 is located within the gate region, and is connected to the first N-type heavily doped layer 31 and the second N-type heavily doped layer 32. The gate electrode 4 covers the sidewalls of channel structure 2, the sidewalls of the first N-type heavily doped layer 31, the sidewalls of the second N-type heavily doped layer 32, and the surface of the second N-type heavily doped layer 32 far from the substrate 1. In some embodiments, the gate electrode 4 may not cover the top of the second N-type heavily doped layer 32. Alternatively, the semiconductor structure may not include the second N-type heavily doped layer 32, and the gate electrode 4 directly covers the side of the second intermediate layer 23 far from the substrate 1.

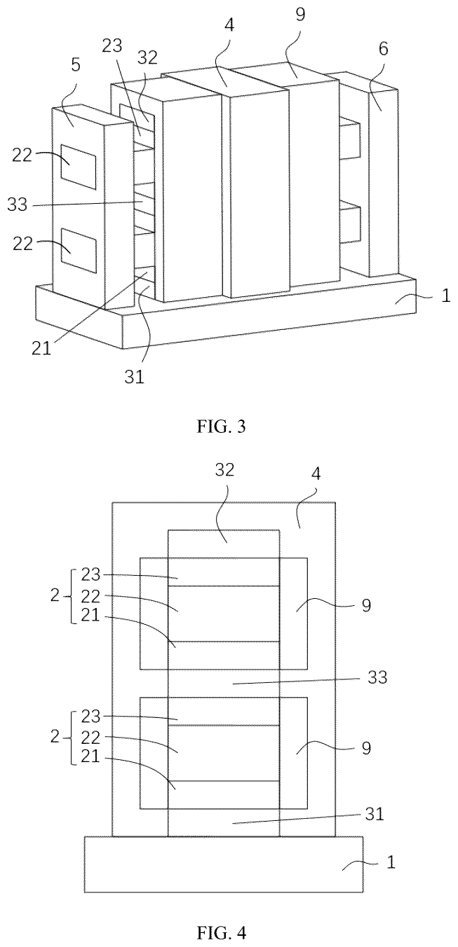

In some embodiments, the semiconductor structure may further include a dielectric layer 9 located in the gate region. The dielectric layer covers at least the sidewalls of the channel layer 22, and the dielectric layer 9 is located between the gate electrode 4 and the channel structure 2. Referring to FIG. 2, FIG. 2 is a schematic cross-sectional diagram of a gate region of a semiconductor structure provided in the embodiment 1 of the present disclosure. In this embodiment, the dielectric layer 9 covers the sidewalls of the channel structure 2, and the gate electrode 4 is connected to the sidewalls of the channel structure 2 through the dielectric layer 9. The dielectric layer 9 acts as the gate medium to reduce gate leakage, improve breakdown voltage, and thus improve the reliability of the device. In some embodiments, a material of the dielectric layer 9 can include SiO₂, SiN, or AlN. Alternatively, the dielectric layer 9 can be a multi-layer structure of materials of at least two of SiO₂, SiN, or AlN.

As shown in FIG. 1, the semiconductor structure further includes a source electrode 5 located in the source region and a drain electrode 6 located in the drain region. The first N-type heavily doped layer 31, the first intermediate layer 21, the second intermediate layer 23, and the second N-type heavily doped layer 32 that are located in the source and drain regions at both sides of the channel structure 2 can be removed to expose the channel layer 22 located in the source and drain regions. The source electrode 5 and the drain electrode 6 surrounding the exposed channel layer 22 can be formed.

In the semiconductor structure provided in the present disclosure, a gate structure is formed by a gate electrode 4 connecting the first N-type heavily doped layer 31 and the second N-type heavily doped layer 32, and the gate structure wraps around the sidewalls of the channel structure 2, thereby increasing the gate control area, making the electric field distribution more uniform, greatly improving the control ability of the gate 4 over the channel layer 22, effectively improving the breakdown voltage, reducing the leakage in the gate area, improving the dynamic characteristics, and improving the efficiency and linearity of the semiconductor structure. Besides, in the semiconductor structure provided in the present disclosure, the first intermediate layer 21, the channel layer 22, and the second intermediate layer 23 are sequentially formed on the first N-type heavily doped layer 31 to ensure the crystal quality of the channel layer 22 and device performance. Furthermore, the first N-type heavily doped layer 31 and the second N-type heavily doped layer 32 replace a metal material as part of the gate structure, and the channel structure 2 can be directly formed on the first N-type heavily doped layer 31. Therefore, the semiconductor structure provided by the present disclosure greatly reduces the difficulty of manufacturing the gate structure wrapping around the sidewalls of the channel layer 22, effectively reducing production costs.

A material of substrate 1 can include Si, SiC, sapphire, or SOI (Silicon On Insulator), etc., which is not limited in the present disclosure.

The channel structure 2 includes a first intermediate layer 21, a channel layer 22, and a second intermediate layer 23 that are stacked. The first intermediate layer 21 and the second intermediate layer 23 can be dielectric material layers, and the channel layer 22 can be a semiconductor material, such that the channel structure can form a channel during working, allowing carriers to communicate between the source electrode 5 and the drain electrode 6 through the channel, achieving conduction of the channel structure 2. A material of the channel structure includes a group-III nitride material. In some embodiments, the materials of the first intermediate layer 21 and the second intermediate layer 23 may include AlN, and the material of the channel layer 22 may include GaN, AlGaN, InGaN, or AlInGaN. The present disclosure does not limit the materials of the channel structure.

The materials of the first N-type heavily doped layer 31 and the second N-type heavily doped layer 32 are group-III nitride materials. In some embodiments, the materials of the first N-type heavily doped layer 31 and the second N-type heavily doped layer 32 include GaN materials heavily doped with Si. In some embodiments, the doping concentration of the first N-type heavily doped layer 31 is greater than 1E18, and the doping concentration of the second N-type heavily doped layer 32 is greater than 1E18, which is not limited by the present disclosure. The gate electrode 4, the source electrode 5, and the drain electrode 6 are usually made of metal materials, such as nickel, nickel manganese alloy, etc., which is not limited in the present disclosure. In some embodiments, the gate electrode 4 forms ohmic contact with the first N-type heavily doped layer 31 and the second N-type heavily doped layer 32 to reduce ohmic contact resistance and improve gate control capability.

The heavily doping of the first N-type heavily doped layer 31 and the second N-type heavily doped layer 32 can be achieved through in-situ doping or implantation of N-type ions (such as Si ions), and the doping concentration can be greater than or equal to 1E18. The present disclosure does not limit the implementation method and doping concentration of heavily doping.

The channel layer 22 can be an N-type lightly doped layer. Similarly, the N-type lightly doped layer can be achieved by in-situ doping or implantation of N-type ions (such as Si ions) to improve electron transfer rate. The doping concentration of N-type ions can be less than 1E18, which is not limited in the present disclosure.

The first N-type heavily doped layer 31 and the second N-type heavily doped layer 32 conduct and combine with the gate electrode 4 to form a gate structure. The gate structure forms a fully enclosed structure for the channel structure 2, which controls the conduction and disconnection of the channel structure 2 through the voltage applied to the gate electrode 4.

The projections of the first N-type heavily doped layer 31 and the second N-type heavily doped layer 32 on the channel structure 2 are located within the gate region. The first N-type heavily doped layer 31 and the second N-type heavily doped layer 32 conduct with gate electrode 4 to control the conduction and disconnection of channel structure 2 through the voltage applied to gate electrode 4. Therefore, the first N-type heavily doped layer 31 and the second N-type heavily doped layer 32 serve as part of the gate structure, and the first N-type heavily doped layer 31 and the second N-type heavily doped layer 32 combine with gate electrode 4 to form a gate structure to control the conduction and closure of channel structure 2.

In some embodiments, the channel layer 22 is a nanowire structure or a nanosheet structure.

In some embodiments, the semiconductor structure may further include a nucleation layer and/or buffer layer between the substrate 1 and the first N-type heavily doped layer 31. A material of the nucleation layer can include, for example, AlN, AlGaN, etc., and a material of the buffer layer can include at least one of AlN, GaN, AlGaN or AlInGaN. The nucleation layer can alleviate the lattice mismatch and thermal mismatch between the epitaxial grown semiconductor layer and the substrate, while the buffer layer can reduce the dislocation density and defect density of the epitaxial grown semiconductor layer, which can improve crystal quality.

### Embodiment 2

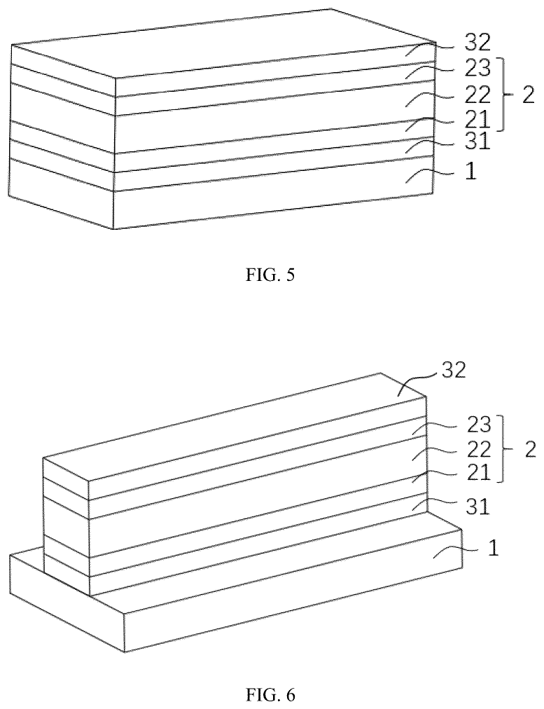

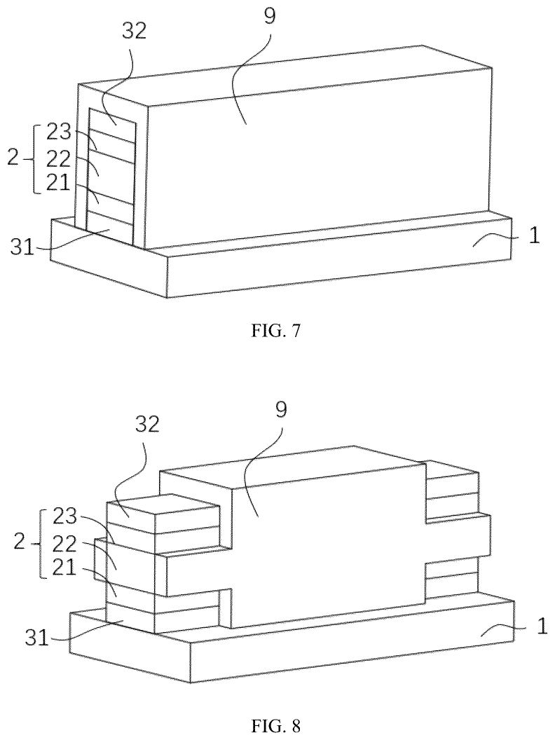

The content of the embodiment 2 is roughly the same as that of the embodiment 1, with the only difference being that, as shown in FIGS. 3 and 4, FIG. 3 is a schematic diagram of a semiconductor structure provided in the embodiment 2 of the present disclosure, and FIG. 4 is a schematic cross-sectional diagram of a gate region of a semiconductor structure provided in the embodiment 2 of the present disclosure. The semiconductor structure provided in the embodiment 2 includes a plurality of the channel structures 2, which are stacked on the substrate 1. The number of the channel structures 2 can be 2 or more, which is not limited in the present disclosure.

The plurality of channel structures 2 that are stacked can save space occupied by the structure, facilitate the manufacturing of smaller devices, improve the channel electron transfer efficiency of the semiconductor structure, and enhance device linearity and stability.

In some embodiments, the semiconductor structure further includes a third N-type heavily doped layer 33 between two adjacent channel structures 2 in the plurality of channel structures 2 (i.e., above the second intermediate layer 23 of the lower channel structure 2 and below the first intermediate layer 21 of the upper channel structure 2), and the projection of the third N-type heavily doped layer 33 on the channel structure 2 is located within the gate region.

In this embodiment, the plurality of channel structures 2 share a gate electrode 4. The gate electrode 4 is connected to the third N-type heavily doped layer 33, and the gate electrode 4 is in Ohmic contact with the third N-type heavily doped layer 33. The first N-type heavily doped layers 31, the second N-type heavily doped layers 32, and the third N-type heavily doped layers 33 serve as part of the gate structure. The first N-type heavily doped layers 31, the second N-type heavily doped layers 32, and the third N-type heavily doped layers 33 are connected to the gate electrode 4 to form a gate structure that surrounds each channel structure in the plurality of channel structures, which forms a fully enclosing structure for each channel structure 2, and controls the conduction and disconnection of each channel structure 2 by voltage applied to the gate electrode 4.

The material of the third N-type heavily doped layer 33 can be the same as that of the first N-type heavily doped layer 31 and the second N-type heavily doped layer 32.

As shown in FIG. 3, in some embodiments, the plurality of channel structures share a gate electrode, a source electrode, and a drain electrode.

In the semiconductor structure provided in the embodiments, a gate structure is formed by a gate electrode 4 connecting the first N-type heavily doped layer 31, the second N-type heavily doped layer 32 and the third N-type heavily doped layers 33, and the gate structure wraps around the sidewalls of the channel structure 2, thereby increasing the gate control area, making the electric field distribution of each channel structure 2 more uniform, greatly improving the control ability of the gate 4 over each channel layer 22, effectively improving the breakdown voltage, reducing the leakage in the gate area, improving the dynamic characteristics, and improving the efficiency and linearity of the semiconductor structure. Besides, in the semiconductor structure provided in the present disclosure, the first intermediate layer 21, the channel layer 22, and the second intermediate layer 23 are sequentially formed on the first N-type heavily doped layer 31 to ensure the crystal quality of the channel layer 22 and device performance. Furthermore, the first N-type heavily doped layer 31 and the second N-type heavily doped layer 32 replace a metal material as part of the gate structure, and the channel structure 2 can be directly formed on the first N-type heavily doped layer 31. Therefore, the semiconductor structure provided by the present disclosure greatly reduces the difficulty of manufacturing the gate structure wrapping around the sidewalls of the channel layer 22, effectively reducing production costs.

### Embodiment 3

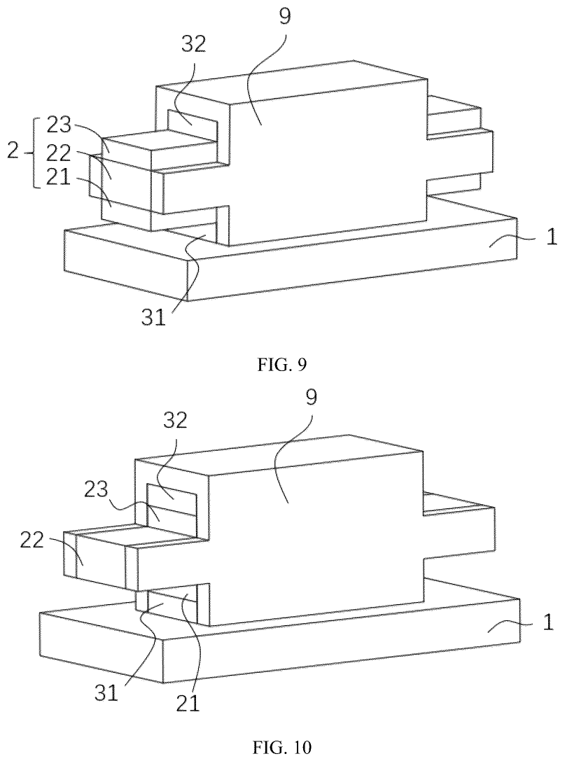

The embodiment 3 provides a manufacturing method for the semiconductor structure provided in the embodiment 1, as shown in FIGS. 5 to 11. FIGS. 5 to 11 are schematic diagrams of a manufacturing process for a semiconductor structure provided in the embodiment 3 of the present disclosure. The manufacturing method includes: providing a substrate 1; on the substrate 1, sequentially manufacturing the first N-type heavily doped layer 31, the channel structure 2, and the second N-type heavily doped layer 32. Manufacturing the channel structure 2 includes manufacturing a first intermediate layer 21, a channel layer 22, and a second intermediate layer 23 that are stacked on the first N-type heavily doped layer 31. The channel structure 2 includes a gate region and source and drain regions located at both sides of the gate region. The method further includes: removing parts of the first N-type heavily doped layer 31 whose projection on the channel structure 2 is within the source region and the drain region, and removing parts of the second N-type heavily doped layer 32 whose projection on the channel structure 2 is within the source region and the drain region; and manufacturing a gate electrode 4 within the gate region, where the gate electrode 4 covers the sidewalls of the first N-type heavily doped layer 31, the channel structure 2, and the second N-type heavily doped layer 32. The gate electrode 4 is connected to the first N-type heavily doped layer 31 and the second N-type heavily doped layer 32. In some embodiments, the gate electrode 4 can also cover the surface of the second N-type heavily doped layer 32 on a side far from the substrate 1.

As shown in FIG. 5, the substrate 1 is provided, and the first N-type heavily doped layer 31, the channel structure 2, and the second N-type heavily doped layer 32 are sequentially manufactured on the substrate 1. The channel structure 2 includes a first intermediate layer 21, a channel layer 22, and a second intermediate layer 23 that are stacked. The manufacturing of the first N-type heavily doped layer 31, the first intermediate layer 21, the channel layer 22, the second intermediate layer 23, and the second N-type heavily doped layer 32 may include: atomic layer deposition (ALD), chemical vapor deposition (CVD), molecular beam epitaxial growth (MBE), plasma enhanced chemical vapor deposition (PECVD), low pressure chemical vapor deposition (LPCVD), metal organic chemical vapor deposition (MOCVD), or any combination thereof, which is not limited in the present disclosure. In some embodiments, when the channel layer 22 is manufactured, N-type doping can be applied to the channel layer 22. The doping concentration of N-type ions is less than 1E18, and the doping method can be in-situ doping or ion implantation, which is not limited in the present disclosure. The materials of the first N-type heavily doped layer 31 and the second N-type heavily doped layer 32 can be GaN materials heavily doped with Si. In some embodiments, the doping concentration of the first N-type heavily doped layer 31 is greater than 1E18, and the doping concentration of the second N-type heavily doped layer 32 is greater than 1E18, which is not limited by the present disclosure.

Referring to FIG. 6, in some embodiments, after sequentially manufacturing the first N-type heavily doped layer 31, the channel structure 2, and the second N-type heavily doped layer 32 on substrate 1, the method further includes: patterning the first N-type heavily doped layer 31, the channel structure 2, and the second N-type heavily doped layer 32, to enable the channel layer 22 to form a nanowire structure or a nanosheet structure. In this embodiment, a material of the channel structure 2 includes a group-III nitride material. The materials of the first intermediate layer 21 and the second intermediate layer 23 can be dielectric materials, the materials of the first intermediate layer 21 and the second intermediate layer 23 include AlN, and the material of the channel layer 22 includes GaN, AlGaN, InGaN, or AlInGaN. The present disclosure does not limit the materials of the channel structure 2.

Referring to FIG. 7, before manufacturing the gate electrode 4 in the gate region, the method further includes: manufacturing a dielectric layer 9 on the sidewalls of the first N-type heavily doped layer 31, the channel structure 2, and the second N-type heavily doped layer 32, and on the top of the second N-type heavily doped layer 32.

Furthermore, referring to FIG. 8, the method further includes: patterning the dielectric layer 9 to expose the first N-type heavily doped layer 31 and the second N-type heavily doped layer 32 located within the source and drain regions. As shown in FIG. 9, after patterning the dielectric layer 9 to expose the first N-type heavily doped layer 31 and the second N-type heavily doped layer 32 located in the source and drain regions, the method further includes: removing the parts of the first N-type heavily doped layer 31 whose projection on the channel structure 2 is within the source region and the drain region, and removing the parts of the second N-type heavily doped layer 32 whose projection on the channel structure 2 is within the source region and the drain region. The removing for the first N-type heavily doped layer 31 and the second N-type heavily doped layer 32 can include wet etching.

In some embodiments, as shown in FIG. 8, patterning the dielectric layer 9 to expose the first N-type heavily doped layer 31 and the second N-type heavily doped layer 32 located within the source and drain regions further includes: patterning the dielectric layer 9 to expose the first intermediate layer 21 and the second intermediate layer 23 within the source and drain regions. Furthermore, as shown in FIG. 10, after removing the parts of the first N-type heavily doped layer 31 whose projection on the channel structure 2 is within the source region and the drain region, and removing the parts of the second N-type heavily doped layer 32 whose projection on the channel structure 2 is within the source region and the drain region, the method further includes: removing the first intermediate layer 21 and the second intermediate layer 23 located in the source and drain regions on the channel structure 2. The removing of the first intermediate layer 21 and the second intermediate layer 23 can include dry etching.

As shown in FIG. 11, after removing the first N-type heavily doped layer 31, the second N-type heavily doped layer 32, the first intermediate layer 21, and the second intermediate layer 23 located in the source and drain regions on the channel structure 2, the dielectric layer 9 is further patterned to expose the first N-type heavily doped layer 31 and the second N-type heavily doped layer 32 located in the gate region. Afterwards, referring to FIG. 1, the gate electrode 4 is manufactured in the gate region, where the gate electrode 4 is connected to the first N-type heavily doped layer 31 and the second N-type heavily doped layer 32. The contact between the gate electrode 4 and the first N-type heavily doped layer 31 and the second N-type heavily doped layer 32 is ohmic contact. The gate electrode 4 is connected to the channel structure 2 through the dielectric layer 9. A source electrode 5 and a drain electrode 6 are respectively manufactured at the source region and the drain region, where the source electrode 5 and the drain electrode 6 both wrap around the channel layer 22.

The manufacturing of the gate electrode 4, the source electrode 5, and the drain electrode 6 may include electron beam evaporation, such as thermal evaporation, sputtering, etc., which is not limited in the present disclosure.

A material of the dielectric layer 9 can include SiO₂, SiN, or AlN. Alternatively, the dielectric layer 9 can be a multi-layer structure of materials of at least two of SiO₂, SiN, or AlN. In this embodiment, the dielectric layer 9 can serve as a gate dielectric layer, to enhance the electric field control ability of the gate electrode. In addition, in the manufacturing process of the semiconductor structure, the dielectric layer 9 can also serve as the etching mask layer for the first N-type heavily doped layer 31, the second N-type heavily doped layer 32, the first intermediate layer 21, and the second intermediate layer 23, thereby effectively simplifying the manufacturing process of the semiconductor structure, improving manufacturing efficiency, and effectively reducing the manufacturing cost of the semiconductor structure.

The gate electrode 4 is usually a metal material, such as nickel, nickel manganese alloy, etc., which is not limited in the present disclosure. In some embodiments, the gate electrode 4 forms ohmic contact with the first N-type heavily doped layer 31 and the second N-type heavily doped layer 32 to reduce Ohmic contact resistance and improve gate control capability.

In some embodiments, before epitaxial growth of the first N-type heavily doped layer 31, a nucleation layer and a buffer layer can be sequentially grown on the side of the substrate 1 close to the first N-type heavily doped layer 31. A material of the nucleation layer can include, for example, AlN, AlGaN, etc., and a material of the buffer layer can include at least one of AlN, GaN, AlGaN or AlInGaN. The manufacturing of the nucleation layer and the buffer layer can be similar to the manufacturing of the first N-type heavily doped layer 31, the first intermediate layer 21, the channel layer 22, the second intermediate layer 23, and the second N-type heavily doped layer 32. The nucleation layer can alleviate the lattice mismatch and thermal mismatch between the epitaxial grown semiconductor layer and the substrate, while the buffer layer can reduce the dislocation density and defect density of the epitaxial grown semiconductor layer, which can improve crystal quality.

### Embodiment 4

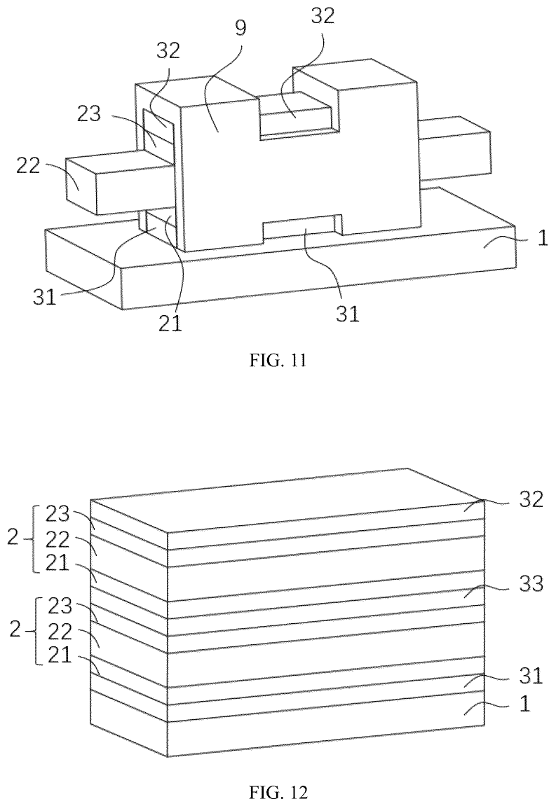

The embodiment 4 provides the manufacturing process of the semiconductor structure provided in the embodiment 2. The content of the embodiment 4 is roughly the same as that of the embodiment 3, with the only difference being that, as shown in FIG. 12, FIG. 12 is an intermediate schematic diagram of a manufacturing process for a semiconductor structure provided in the embodiment 4 of the present disclosure. Combined with FIGS. 3 to 4, manufacturing the channel structure 2 includes manufacturing a plurality of the channel structures 2, which are stacked on the substrate 1.

The manufacturing of the plurality of channel structures 2 is similar to the manufacturing of the first N-type heavily doped layer 31, the first intermediate layer 21, the channel layer 22, the second intermediate layer 23, and the second N-type heavily doped layer 32, and will not be repeated here.

In some embodiments, manufacturing the plurality of channel structures 2 further includes manufacturing at least one third N-type heavily doped layer 33, where each third N-type heavily doped layer 33 is between two adjacent channel structures 2 in the plurality of channel structures 2 (i.e., above the second intermediate layer 23 of the lower channel structure 2 and below the first intermediate layer 21 of the upper channel structure 2). After manufacturing the plurality of channel structures 2, when removing the parts of the first N-type heavily doped layer 31 whose projection on the channel structure 2 is within the source region and the drain region, and the parts of the second N-type heavily doped layer 32 whose projection on the channel structure 2 is within the source region and the drain region, parts of the third N-type heavily doped layer(s) 33 whose projection on the channel structure 2 is within the source and drain regions can also be removed. The gate electrode 4 is connected to the third N-type heavily doped layer 33, and the gate electrode 4 is in ohmic contact with the third N-type heavily doped layer 33.

The manufacturing of the third N-type heavily doped layer 33 is similar to the manufacturing of the first N-type heavily doped layer 31, the first intermediate layer 21, the channel layer 22, the second intermediate layer 23, and the second N-type heavily doped layer 32. The implementation of etching the parts of the third N-type heavily doped layer 33 whose projection on the channel structure 2 is within the source and drain regions is similar to the implementation of etching the parts of the first N-type heavily doped layer 31 whose projection on the channel structure 2 is within the source region and the drain region, and the parts of the second N-type heavily doped layer 32 whose projection on the channel structure 2 is within the source region and the drain region, and will not be repeated here.

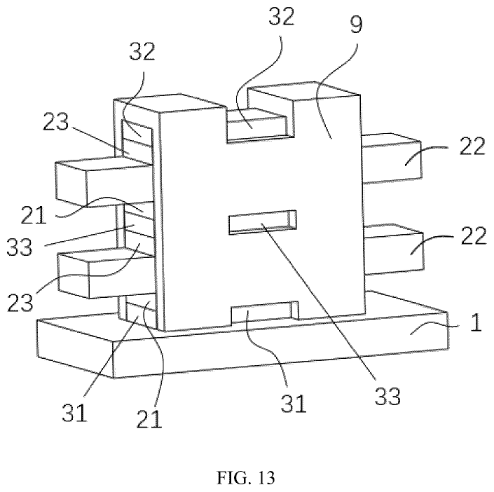

As shown in FIG. 13, FIG. 13 is another intermediate schematic diagram of a manufacturing process for a semiconductor structure provided in the embodiment 4 of the present disclosure. Removing the parts of the first N-type heavily doped layer 31 whose projection on the channel structure 2 is within the source region and the drain region, and the parts of the second N-type heavily doped layer 32 whose projection on the channel structure 2 is within the source region and the drain region includes: removing the parts of the third N-type heavily doped layer 33 whose projection on the channel structure 2 is within the source and drain regions. In some embodiments, when patterning the dielectric layer 9 to expose the first N-type heavily doped layer 31 and the second N-type heavily doped layer 32 located in the source region and drain region on the channel structure 2, the third N-type heavily doped layer 33 in the source region and drain region on the channel structure 2 can be simultaneously exposed, such that the third N-type heavily doped layer 33, the first N-type heavily doped layer 31 and the second N-type heavily doped layer 32 can be removed simultaneously.

In addition, when further patterning the dielectric layer 9 to expose the first N-type heavily doped layer 31 and the second N-type heavily doped layer 32 located in the gate region on the channel structure 2, the third N-type heavily doped layer 33 located in the gate region on the channel structure 2 can be also simultaneously exposed, such that when manufacturing the gate electrode 4, the gate electrode 4 can be connected to the third N-type heavily doped layer 33.

The specific structure, principle, function, and effect in the embodiments of the manufacturing method are similar to those described in the embodiments of the semiconductor structure mentioned above. Reference can be made to the content described in the structural embodiments, which will not be repeated here.

It should be noted that, in the embodiments, a certain material is represented by chemical elements, but a molar ratio of each chemical element in the material is not limited. For example, GaN materials contain Ga element and N element, but the molar proportions of Ga element and N element are not limited; AlGaN materials contain three elements, Al, Ga and N, but their molar proportions are not limited.

It should be noted that, while this specification contains many specific embodiments, these embodiments should not be understood as limiting the scope of any invention or what may be claimed, but are used to describe features of specific embodiments of particular inventions. Certain features described in a single embodiment in this specification may also be implemented in combination in other embodiments. On the other hand, the various features described in various embodiments can also be implemented in any suitable combination. Furthermore, although features may function as described above in certain combinations and even be originally claimed as such, one or more features from a claimed combination may in some cases be removed from the combination and the claimed protected combination may point to a subcombination or a variation of a subcombination.

Therefore, specific embodiments of the present disclosure have been described. Other embodiments are within the scope of the appended claims. In some cases, the features recited in the claims can be performed in a different order and still achieve the desirable result. In addition, the order of the features depicted in the accompanying drawings is not necessary in a particular order or sequential order to achieve the desirable results. In some implementations, it may also be multitasking and parallel processing.

The above is only some embodiments of the present disclosure and is not intended to limit the present disclosure. Any modifications, equivalent replacements, improvements, etc. made within the spirit and principles of the present disclosure shall be included in the scope of protection of the present disclosure.

What is claimed is:

1. A semiconductor structure, comprising:
a substrate;
a channel structure on the substrate, wherein the channel structure comprises a first intermediate layer, a channel layer, and a second intermediate layer that are stacked on the substrate, and the channel structure comprises a gate region, and a source region and a drain region at both sides of the gate region;
a first N-type heavily doped layer and a second N-type heavily doped layer, wherein the first N-type heavily doped layer is between the substrate and the channel structure, and the second N-type heavily doped layer is on a side of the channel structure far from the substrate, and projection of the first N-type heavily doped layer on the channel structure and projection of the second N-type heavily doped layer on the channel structure are located within the gate region; and
a gate electrode within the gate region, wherein the gate electrode covers sidewalls of the first N-type heavily doped layer, the channel structure, and the second N-type heavily doped layer.

2. The semiconductor structure according to claim 1, wherein the gate electrode is in ohmic contact with the first N-type heavily doped layer and the second N-type heavily doped layer.

3. The semiconductor structure according to claim 1, wherein the semiconductor structure comprises:
a plurality of the channel structures that are stacked on the substrate; and
a third N-type heavily doped layer between adjacent channel structures of the plurality of channel structures, and projection of the third N-type heavily doped layer on the channel structure is located within the gate region.

4. The semiconductor structure according to claim 3, wherein the plurality of channel structures share the gate electrode, the gate electrode covers sidewalls of the third N-type heavily doped layer, and the gate electrode is in ohmic contact with the third N-type heavily doped layer.

5. The semiconductor structure according to claim 1, further comprising:
a dielectric layer on the gate region, wherein the dielectric layer covers the sidewalls of the channel layer, and the dielectric layer is between the gate electrode and the channel layer.

6. The semiconductor structure according to claim 1, wherein the channel layer is a nanowire structure or a nanosheet structure.

7. The semiconductor structure according to claim 1, wherein a material of the channel structure comprises a group-III nitride material.

8. The semiconductor structure according to claim 1, wherein materials of the first intermediate layer and the second intermediate layer comprises AlN; and a material of the channel layer comprises GaN, AlGaN, InGaN, or AlInGaN.

9. The semiconductor structure according to claim 1, further comprising:
a source electrode and a drain electrode respectively at the source region and the drain region, wherein the source electrode and the drain electrode both wrap around the channel layer.

10. The semiconductor structure according to claim 1, wherein the channel layer is an N-type lightly doped layer, and doping concentration of N-type ions for the channel layer is less than 1E18.

11. A manufacturing method for a semiconductor structure, comprising:
providing a substrate;
sequentially manufacturing a first N-type heavily doped layer, a channel structure, and a second N-type heavily doped layer on the substrate, wherein manufacturing the channel structure comprises: manufacturing a first intermediate layer, a channel layer, and a second intermediate layer that are stacked on the first N-type heavily doped layer, wherein the channel structure comprises a gate region, and a source region and a drain region at both sides of the gate region;
removing parts of the first N-type heavily doped layer whose projection on the channel structure is within the source region and the drain region, and parts of the second N-type heavily doped layer whose projection on the channel structure is within the source region and the drain region; and
manufacturing a gate electrode within the gate region, wherein the gate electrode covers sidewalls of the first N-type heavily doped layer, the channel structure, and the second N-type heavily doped layer.

12. The manufacturing method according to claim 11, wherein before manufacturing the gate electrode within the gate region, the manufacturing method further comprises:
manufacturing a dielectric layer on the sidewalls of the first N-type heavily doped layer, the channel structure, and the second N-type heavily doped layer, and on a top of the second N-type heavily doped layer; and
patterning the dielectric layer to expose a part of the first N-type heavily doped layer in the gate region and a part of the second N-type heavily doped layer in the gate region, wherein the gate electrode is connected to the first N-type heavily doped layer and the second N-type heavily doped layer, and the gate electrode is connected to the channel structure through the dielectric layer.

13. The manufacturing method according to claim 12, wherein removing the parts of the first N-type heavily doped layer whose projection on the channel structure is within the source region and the drain region, and the parts of the second N-type heavily doped layer whose projection on the channel structure is within the source region and the drain region comprises:
patterning the dielectric layer to expose parts of the first N-type heavily doped layer within the source region and the drain region, and parts of the second N-type heavily doped layer within the source region and the drain region; and
removing the parts of the first N-type heavily doped layer whose projection on the channel structure is within the source region and the drain region, and the parts of the second N-type heavily doped layer whose projection on the channel structure is within the source region and the drain region.

14. The manufacturing method according to claim 13, wherein
patterning the dielectric layer to expose the parts of the first N-type heavily doped layer within the source region and the drain region, and the parts of the second N-type heavily doped layer within the source region and the drain region comprises:
patterning the dielectric layer to expose the parts of the first N-type heavily doped layer within the source region and the drain region, the parts of the second N-type heavily doped layer within the source region and the drain region, parts of the first intermediate layer within the source region and the drain region, and parts of the second intermediate layer within the source region and the drain region; and
the method further comprises:
removing the parts of the first intermediate layer within the source region and the drain region, and the parts of the second intermediate layer within the source region and the drain region.

15. The manufacturing method according to claim 14, further comprising:
respectively manufacturing a source electrode and a drain electrode at the source region and the drain region, wherein the source electrode and the drain electrode both wrap around the channel layer.

16. The manufacturing method according to claim 11, wherein the gate electrode is in ohmic contact with the first N-type heavily doped layer and the second N-type heavily doped layer.

17. The manufacturing method according to claim 12, wherein before manufacturing the dielectric layer on the sidewalls of the first N-type heavily doped layer, the channel structure, and the second N-type heavily doped layer, and on the top of the second N-type heavily doped layer, the manufacturing method further comprises:
patterning the first N-type heavily doped layer, the channel structure, and the second N-type heavily doped layer, to enable the channel layer to form a nanowire structure or a nanosheet structure.

18. The manufacturing method according to claim 11, wherein
manufacturing the channel structure comprises:
manufacturing a plurality of the channel structures that are stacked on the substrate; and
the method further comprises:
manufacturing a third N-type heavily doped layer between adjacent channel structures in the plurality of channel structures, wherein the gate electrode is connected to the third N-type heavily doped layer, and the gate electrode is in ohmic contact with the third N-type heavily doped layer.

19. The manufacturing method according to claim 18, wherein removing the parts of the first N-type heavily doped layer whose projection on the channel structure is within the source region and the drain region, and the parts of the second N-type heavily doped layer whose projection on the channel structure is within the source region and the drain region comprises:
removing the parts of the first N-type heavily doped layer whose projection on the channel structure is within the source region and the drain region, the parts of the second N-type heavily doped layer whose projection on the channel structure is within the source region and the drain region, and parts of the third N-type heavily doped layer whose projection on the channel structure is within the source region and the drain region.

20. The manufacturing method according to claim 11, further comprising:
performing N-type doping on the channel layer, wherein doping concentration of N-type ions is less than 1E18.
